(19) United States
(12) Patent Application Publication
(10) Pub. No.: US 2010/0275975 A1
(43) Pub. Date: Nov. 4, 2010

(54) SOLAR PANEL SYSTEMS

(76) Inventors: Jonathan Monschke, Joseph, OR (US); Louis D. Perry, Joseph, OR (US); Ben Henson, Enterprise, OR (US)

Correspondence Address: KOLISCH HARTWELL, P.C., 200 PACIFIC BUILDING, 520 SW YAMHILL STREET, PORTLAND, OR, 97204, US

(21) Appl. No.: 12/771,229

(22) Filed: Apr. 30, 2010

Related U.S. Application Data
(60) Provisional application No. 61/215,277, filed on Apr. 30, 2009.
(60) Provisional application No. 61/216,624, filed on May 18, 2009.

(51) Int. Cl. H01L 31/048

(52) U.S. Cl. 136/251

(57) ABSTRACT

A clamping assembly for securing two or more solar panels to a frame assembly is disclosed. The clamping assembly may include an extruded first clamping member having first and second surfaces and a receiving portion disposed between the first and second surfaces, the first and second surfaces being within a first plane and the first clamping member being free from a void between the first and second surfaces; a second clamping member configured to be attached to the receiving portion, first and second solar panels being disposed between the first and second clamping members; and a first fastener configured to be at least partially received by the receiving portion of the first clamping member and the second clamping member to secure together the first and second clamping members and the first and second solar panels.

### CROSS-REFERENCE TO RELATED APPLICATIONS

This application claims priority under 35 U.S.C. §119(e) to U.S. Provisional Patent Application Ser. No. 61/215,277 entitled “Solar Arrays” and filed Apr. 30, 2009; and to U.S. Provisional Patent Application Ser. No. 61/216,624 entitled “Solar Arrays” and filed May 18, 2009. The complete disclosures of the above applications are herein incorporated by reference for all purposes.

### BACKGROUND OF THE DISCLOSURE

Solar panels have increasingly been used as an alternative energy source due to the increase in cost and environmental impact of fossil fuels. One drawback to the use of solar panels is that a minimum area of exposure is needed for the collection of usable amounts of solar energy, and as such, solar panels generally occupy a large amount of space. Often, solar panels are mounted to rooftops of existing buildings with mounting structures attached to the rooftop, so that the solar panels do not occupy space that would otherwise have alternative uses. However, those solar panels and/or mounting structures can adversely affect the architectural and/or structural integrity of the roof.

Ground-mounted solar panel systems or arrays also have been constructed by mounting solar panels on supports in vacant land areas, but those systems take up space that could otherwise have alternative uses. Moreover, existing ground-mounted solar panel systems are generally difficult to assemble and disassemble; which in turn makes it difficult to move the solar panel system or to repair, replace or otherwise maintain the solar panels. Solar collection farms (which may include two or more solar panel systems) have been built in exceedingly sunny locations, such as deserts where the land is not otherwise useful, but these suffer from the problem of conducting the solar energy to the point of use, and do not enable individual households and businesses to control their individual usage of solar energy.

### SUMMARY OF THE DISCLOSURE

Some embodiments provide a clamping assembly for securing two or more solar panels to a frame assembly. The clamping assembly may include an extruded first clamping member having first and second surfaces and a receiving portion disposed between the first and second surfaces, the first surface configured to support a portion of a first solar panel, and the second surface configured to support a portion of a second solar panel, the first and second surfaces being within a first plane and the first clamping member being free from a void between the first and second surfaces; a second clamping member configured to be attached to the receiving portion, the first and second solar panels being disposed between the first and second clamping members; and a first fastener configured to be at least partially received by the receiving portion of the first clamping member and the second clamping member to secure together the first and second clamping members and the first and second solar panels.

Some embodiments provide a solar panel racking system. The solar panel racking system may include a plurality of clamping assemblies, including an extruded first clamping member having a receiving portion disposed between first and second surfaces, the first surface configured to support a portion of a first solar panel, and the second surface configured to support a portion of a second solar panel, the first and second surfaces being within a first plane and the first clamping member being free from a void between the first and second surfaces; a second clamping member configured to be attached to the receiving portion, the first and second solar panels being disposed between the first and second clamping members; and a first fastener configured to be at least partially received by the receiving portion of the first clamping member and the second clamping member to secure together the first and second clamping members and the first and second solar panels; and a frame assembly configured to support the plurality of clamping assemblies on a surface.

Some embodiments provide a solar panel system. The solar panel system including a plurality of solar panels, including first and second solar panels; a plurality of clamping assemblies, including an extruded first clamping member having a receiving portion disposed between first and second surfaces, the first surface configured to support a portion of the first solar panel, and the second surface configured to support a portion of the second solar panel, the first and second surfaces being within a first plane and the first clamping member being free from a void between the first and second surfaces; a second clamping member configured to be attached to the receiving portion, the first and second solar panels being disposed between the first and second clamping members; and a first fastener configured to be at least partially received by the receiving portion of the first clamping member and the second clamping member and to secure together the first and second clamping members and the first and second solar panels; and a frame assembly configured to support the plurality of solar panels on a surface, wherein the plurality of clamping assemblies secure the plurality of solar panels to the frame assembly.

### BRIEF DESCRIPTION OF THE DRAWINGS

FIG. 1 is an isometric view of an example of a solar panel system.

FIG. 2 is an isometric view another example of a frame assembly for the solar panel system of FIG. 1.

FIG. 3 is an isometric partial view of the frame assembly of FIG. 2 showing an example of support members connected via slip joints.

FIG. 4 is a sectional view of the solar panel system of FIG. 1 taken along lines 4-4 in FIG. 1 shown without solar panels and showing an example of a clamping assembly.

FIG. 5 is an isometric view of an example of a clamping member of the clamping assembly of FIG. 4.

FIG. 6 is a longitudinal sectional view of another example of a clamping assembly of the solar panel system of FIG. 1.

FIG. 7 is a longitudinal sectional view of another example of a clamping assembly of the solar panel system of FIG. 1.

FIG. 8 is a longitudinal sectional view of another example of a clamping assembly of the solar panel system of FIG. 1.

FIG. 9 is a side view of another example of a solar panel system.

FIG. 10 is a partial view of the solar panel system of FIG. 9 shown with a longitudinal section view of the clamping assembly of FIG. 7.

FIG. 11 is a partial view of FIG. 10 showing a longitudinal section view of the clamping assembly of FIG. 7 and a frame assembly.

FIG. 12 is a partial isometric view of another example of a solar panel system shown with the clamping assembly of FIG. 8.

### DETAILED DESCRIPTION OF THE DISCLOSURE

FIG. 1 shows an example of a solar panel array or system 20. Unless specifically excluded, solar panel system 20 may include one or more components of the other solar panel systems described in this specification. The solar panel system may include a ground-mounted frame assembly 22 for mounting a roof 24 with one or more solar panels 26. The frame assembly also may be used to mount one or more electrical components 28 related to a solar energy system, which may include an inverter, control apparatus, meter, and/or wiring connecting the solar panel(s) to other electrical components.

The frame assembly and roof may be configured to define a covered space 30 below the solar panels that may be used for storage of household and/or business related items, and/or for recreation. For example, the solar panel system may be used as a vehicle port, a covered picnic area, outdoor tables, etc. The solar panel system may include any desired number and size of solar panels 26 oriented in any desired orientation. When solar panel system 20 is provided without solar panels 26, that system may sometimes be referred to as a “solar panel racking system 31.”

As shown in FIGS. 2-3, the frame assembly may include a plurality of support members 32, such as vertical support members 34, horizontal support members 36, and transverse support members 38. Frame assembly 22 also may include any suitable structure configured to allow the members to be easily coupled to and/or de-coupled from one another. For example, the frame assembly may include one or more slip joints 40, as shown in FIG. 3. Any suitable fastener(s) (not shown), which may include bolts, screws, pins, etc., may be used to secure the support members to the slip joints. As such, the frame assembly may be modular, and its size and/or shape may readily be adjusted by adding or removing slip joints 40 and/or support members.

Moreover, the slip joints may enable rapid assembly and disassembly of the frame assembly, thereby enabling a user to easily move components of solar panel system 20 constructed with the frame assembly, or to repair, replace or otherwise maintain solar panel(s) coupled to the frame assembly. Although support members 32 are shown to include slip joints 40, the support members may alternatively, or additionally, include any suitable connectors configured to allow the support members to be connected to form the frame assembly.

Any number and/or size of the vertical, horizontal and/or transverse support members may be used to construct a frame assembly having the desired dimensions and structural stability. Frame assembly 22 may include any suitable combination of support members 32. For example, FIG. 1 shows a first example of a frame assembly with four vertical support members 34, while FIG. 2 shows a second example of a frame assembly with six to nine of those support members.

Some of support members 32 may include telescoping portions that enable a user to telescopically adjust the length of support member 32 to any desired length. When assembled, the support members may define a substantially planar support region 42 (or purchase) for supporting the weight of roof 24 and for securing the roof to the frame assembly in a desired position and orientation relative to the ground. The support members may be made of titanium, graphite, powder coated steel, aluminum, and/or any other suitable materials.

Referring again to FIG. 1, the vertical support members of the frame assembly may be mounted to the ground. For example, the vertical support members may be anchored in a concrete foundation. Alternatively, or additionally, the vertical support members may be attached to footings 43 (shown in dashed lines in FIG. 1) that provide additional stability to the frame assembly. Some frame assemblies 22 may include vertical support members 34 that are not securely anchored to the ground, such that the solar panel system is moveable. For example, one or more wheels (not shown) may be attached to the vertical support members.

As discussed above, the roof may be attached to the substantially planar support region of the frame assembly, thereby positioning the roof in a desired position and orientation relative to the ground and the sky. The roof may be comprised of either (1) a roof structure 44 that may be attached to the substantially planar support region of the frame assembly such that one or more solar panels 26 may be attached to the roof structure; or (2) one or more solar panels 26 directly attached to the substantially planar support region of the frame assembly without a roofing structure 44 between the substantially planar support region and the solar panels, such that the solar panels form roof 24 that defines covered space 30 with the frame assembly.

### I. Roofs Comprised of Roof Structures Attached to the Frame Assembly and One or More Solar Panels Attached to the Roof Structure

FIG. 1 shows solar panel system 20 having a roof 24 comprised of a roof structure 44 and a plurality of solar panels 26 affixed to the roof structure by a racking assembly 46. The roof structure may be constructed of one or more roofing materials, including metal, plastic, vinyl, glass, etc. The roof structure also may have any desired shape consistent with its functions, including flat panel standing seam roofing, a sheet of flat roofing material, corrugated roofing, and/or any other suitable roofing that may be coupled to the horizontal and/or transverse support members that define the substantially planar support region of the frame. For example, the roof structure may be attached to purlins, joists, etc. that are attached by any suitable fasteners (including bolts, screws, etc.) to the substantially planar support region of the frame assembly.

The roof structure may be selected to inhibit and/or prevent the elements from affecting the space beneath the roof. For example, the roof structure may be substantially or completely water tight, such as through the use of contiguous expanses of material, welds, seals and/or sealants, which inhibit moisture from passing through the roof and into the space covered by the roof. Moreover, any portion of the roof structure may be selected to be transparent, translucent, or opaque, depending on the desired application, so as to allow, inhibit or prevent light from passing through the roof structure.

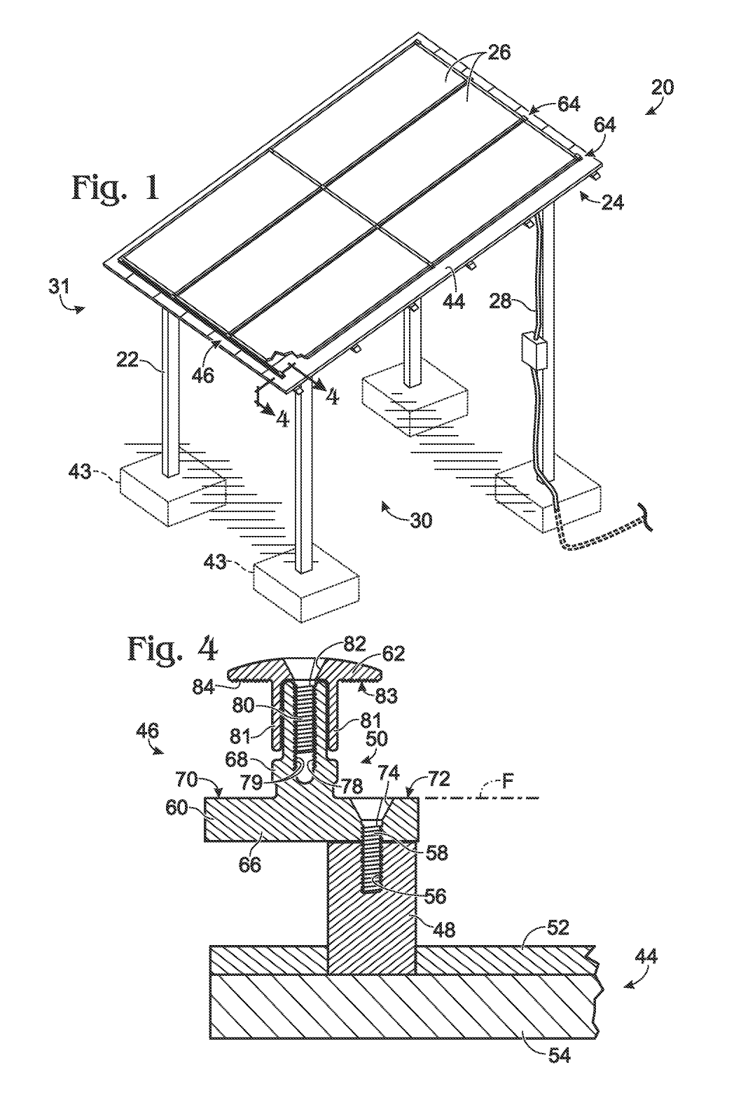

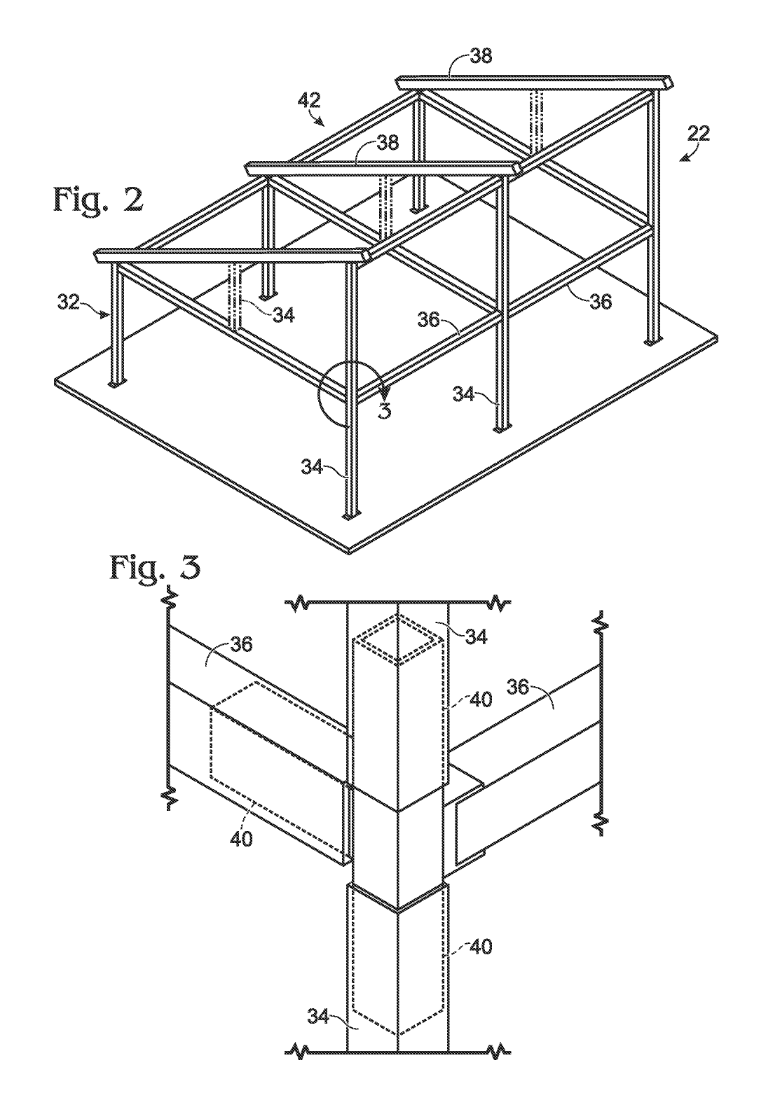

FIG. 4 shows a cross sectional side view of the roof of the solar panel system shown in FIG. 1. As shown in FIG. 1, one or more solar panels 26 (i.e., Photovoltaic Panels, or PV Modules) may be attached to the roof structure by a racking assembly 46, which may secure the solar panels in generally the same orientation as the roof, or may secure the solar panels in a slightly different orientation than the roof. The racking assembly may include a plurality of mounts 48 and a plurality of clamping assemblies 50, as shown in FIG. 4.

The mounts may include any suitable structure configured to securely fasten to the roof structure and may be attached to clamping assembly 50. The mount may include, for example, an S-5 clamp that may be securely fastened to a standing seam 52 of a flat panel standing seam roof structure 54, and that includes a threaded mounting aperture 56 for receiving a bolt or other fastener 58, although any suitable mount 48 may be used that securely attaches to the selected type of roof structure.

The plurality of mounts may be attached to roof structure 44 at positions generally corresponding to locations where it may be desirable to couple clamping assembly 50 to the roof structure. Some of the plurality of mounts may have different heights than others of the plurality of mounts, or may include telescoping members that allow for adjustment of the height of the mounts, thereby enabling a user to select the positions of the clamping assemblies relative to the roof structure, and thus to adjust the position of the solar panels relative to the roof structure.

The clamping assemblies may include any suitable structure configured to secure one, two, three, four or more solar panels 26 to frame assembly 22. For example, each clamping assembly 50 may include a first clamping member 60 and a second clamping member 62. The first clamping member may be configured to be attached to mount 48. Second clamping member 62 may be configured to be attached to the first clamping member, such as to a channel receiver (further discussed below). The first and second clamping members may function together to clamp one side of one or more solar panels therebetween. In other words, first and second solar panels may be disposed between the first and second clamping members.

As shown in FIG. 1, the first and/or second clamping members of each clamping assembly may be generally elongate structures having lengths that span the width of one or more solar panels 26. For example, the first and/or second clamping members each may have a length that is approximately or precisely a multiple of the width of a solar panel. Alternatively, the first clamping member may span the width of one or more solar panels 26, while two or more, much shorter, second clamping members may be attached to the first clamping member. Those second clamping members may span any suitable widths and may be separated by any suitable distances. For example, a first clamping member 60 may span the width of three solar panels 26, while second clamping members 62 may span the 1/10, 1/15, 1/20 or less of the width of a solar panel 26 and may be attached at different portions of the first clamping member, such as adjacent to corner portions 64 of those solar panels, as shown in FIG. 1.

As shown in FIG. 4, the first clamping member may include a base portion 66 and a channel receiver or receiving portion 68 extending transversely or tangentially from the base portion. The base portion may include a first surface 70 and a second surface 72. The first surface may be configured to support a portion of a first solar panel, while the second surface may be configured to support a portion of a second solar panel. Additionally, or alternatively, the first and second surfaces may be coplanar or within a first plane F. The channel receiver may sometimes be described as being disposed between the first and second surfaces. Although first and second surfaces 70, 72 are described to support a portion of a single solar panel 26, the first and/or second surfaces may each support portions of two or more solar panels 26.

Alternatively, or additionally, the first clamping member may be free from (or without) one or more voids between the first and second surfaces. In other words, first clamping member 60 may not include any channels, slots, apertures, etc. between the first and second surfaces and/or within first plane F. When the first clamping member is free from void(s) between the first and second surface, that clamping member may provide more structural support of the solar panels compared to other clamping members with void(s) between those surfaces. The additional structural support provided by the first clamping member may allow the solar panel system to use frame assemblies with less support members and/or without a roof structure, as further discussed below.

The first and/or second surfaces of first clamping member 60 may include one or more channels or grooves 74 configured to at least partially receive one or more mount fasteners 58. Groove 74 may span any suitable length of the surface. Mount fastener 58 may in turn be engaged with a fastening aperture 56 of the mount to secure the first clamping member to the mount. In other words, the mount fastener may be configured to be at least partially received in groove 74 and to secure the first clamping member to the frame assembly.

Alternatively, or additionally, the base member may include a plurality of spaced-apart apertures (not shown) configured to at least partially receive the mount fasteners. Although base portion 66 is shown to include a single groove 74, the base portion may include two, three, four, or more grooves. Additionally, although second surface 72 of base portion 66 is shown to include groove 74, the first surface may additionally, or alternatively, include one or more grooves 74. For example, both the first and second surfaces may include one or more grooves 74 such that both surfaces may be attached to one or more mounts 48 via mount fasteners 58.

Similar to the base portion, the channel receiver also may have a length spanning the length of the first clamping member, and may define a channel 78 having a plurality of channel ridges 79 for receiving one or more clamp fasteners 80 at any position(s) along its length. The channel receiver may have a height that is substantially the same as, or slightly less than the height of solar panel 26, such that when solar panel 26 is seated on the first or second surface of the base portion, on either side of the channel receiver, the top surface of the solar panel is flush with or slightly higher than the top of the channel receiver.

The first clamping member may be formed of a single unitary piece of extruded material. The first and/or second clamping members may each be extruded and/or a unitary member. In other words, the first clamping member (and/or the second clamping member) may be a singular component that does not consist of multiple components. Alternatively, the first clamping member may include several components welded or otherwise secured together.

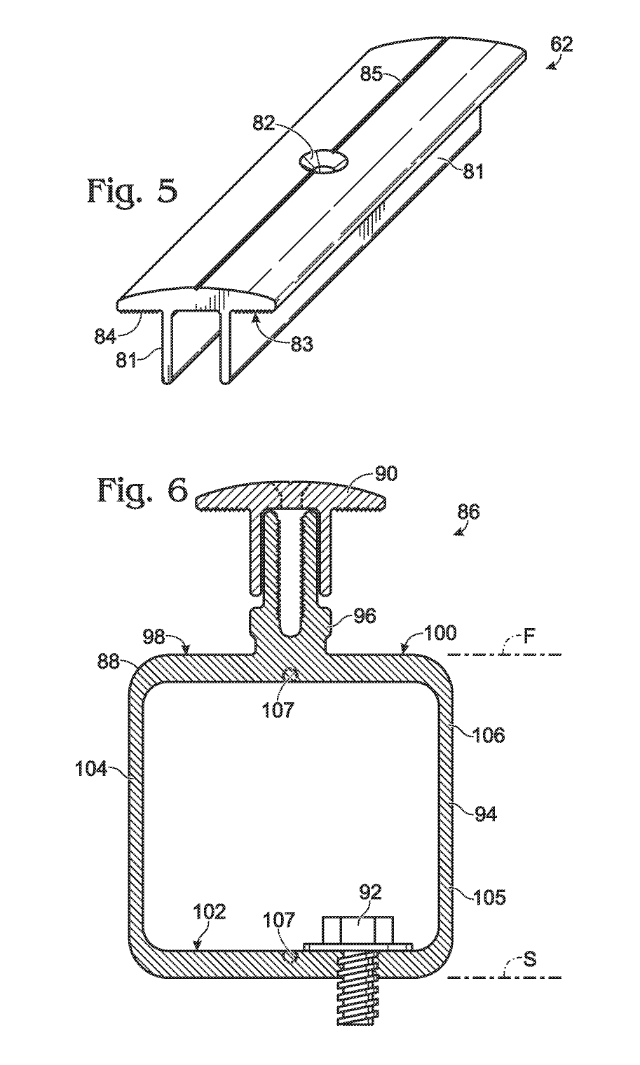

Second clamping member 62 may include one or more receiving walls 81 and one or more apertures 82. The receiving walls may be complementary with the channel receiver of the first clamping members. Apertures 82 may be located along any suitable portions of the second clamping member for receiving one or more clamp fasteners 80. The second clamping member may further include contact surfaces 83 having clamp ridges 84 for retaining the solar panels, as shown in FIGS. 4-5. The clamp fasteners may be inserted through the apertures in the second clamping member and engaged with the channel receiver at any position along its length to secure the second clamping member to the first clamping member. In other words, the clamp fastener may be configured to be at least partially received by aperture 82 and channel receiver 68 to secure together the first and second clamping members and first and second solar panels 26.

Although second clamping member 62 is shown to include a single aperture 82, the second clamping member may include any suitable number of apertures. Additionally, aperture 82 is shown to be centrally disposed on the second clamping member, the aperture may be in any suitable portion(s) of the second clamping member, such as the end portion(s). Second clamping member 62 also may include one or more channels 85, which may be configured to drain and/or direct water falling on the second clamping member. Unless specifically excluded, clamping assembly 50 may include one or more components of other clamping assemblies described in this specification.

When one or more solar panels 26 are seated on the first and second surfaces of the base portion (on either side of the channel receiver) and the second clamping member is secured to the first clamping member, the contact surfaces of the second clamping member engage the solar panel(s) and clamp the solar panel(s) to the base portion of the first clamping member, thereby securing the solar panel(s) in place.

In some embodiments, second clamping member 62 may include one or more rubber gaskets (not shown) that function as a pad for preventing damage to the solar panels, as a frictional surface for preventing the solar panel(s) from moving relative to the clamping assembly, and/or as a seal that inhibits or prevents moisture from passing between the solar panel and the clamping assembly. Although second clamping member 62 is shown to include a particular structure, the second clamping member may include any suitable structure configured to attach to the first clamping member and secure one or more solar panels 26. For example, second clamping member 62 may exclude one or more receiving walls 81.

When assembling solar panel system 20, at least a pair of clamping assemblies is required to secure a solar panel 26 to roof structure 44. For example, a row of solar panels 26 may include one of a pair of clamping assemblies 50 on opposing sides of the row of solar panels 26. For solar panel systems 20 having more than one row of solar panels (such as shown in FIG. 1, which includes two rows of solar panels 26), a single clamping assembly 50 may be used between adjacent rows, because each clamping assembly may be adapted to clamp one side of a row of solar panel 26 on either side of channel receiver 68. In other words, a clamping assembly 50 may be adapted to clamp one, two, three, four, or more solar panels 26.

In some cases, racking assembly 46 also may include one or more seals (not shown) having a length that extends the length of one or more solar panels 26. The seals may function to plug the gaps between solar panels 26 at positions where the clamping assemblies do not engage the solar panels, thereby forming a moisture barrier that may inhibit or prevent moisture from passing between the spaces between adjacent solar panels 26.

### II. Roofs Comprised of One or More Solar Panels Directly Attached to the Frame Assembly

FIG. 6 shows an example of a clamping assembly 50, which is generally indicated at 86, that may be used to directly attach solar panels 26 to frame assembly 22 such that solar panel system 20 is free from a roofing structure between the racking assembly and the frame assembly. Unless specifically excluded, clamping assembly 86 may include one or more components of clamping assembly 50 and/or other clamping assemblies described in this specification. Clamping assembly 86 may include a first clamping member 88, a second clamping member 90, and a fastener 92, as shown in FIG. 6.

The first clamping member may include a base portion 94 and a channel receiver (or receiving portion) 96. The base portion may include a first surface 98 and a second surface 100. The first surface may be configured to support a portion of a first solar panel, while the second surface may be configured to support a portion of a second solar panel. The first and second surfaces may be coplanar or within first plane F. Alternatively, the first and second surface may be in separate planes (not shown). Additionally, or alternatively, the first clamping member may be free from one or more voids between the first and second surfaces.

Base portion 94 also may include a third surface 102 within a second plane S parallel to first plane F. Additionally, the base portion may include a first wall 104 and a second wall 105, which may connect the first and second surfaces and the third surface to form a closed hollow structure 106, as shown in FIG. 6. The first and second walls may be generally perpendicular to the first, second, and/or third surfaces. Additionally, base portion 94 may include one or more openings 107 configured to receive an end cap (not shown). Fastener(s) 92 may be configured to secure third surface 102 to the frame assembly.

FIG. 7 shows another example of a clamping assembly 50, which is generally indicated at 108, that may be used to directly attach solar panels 26 to frame assembly 22 such that solar panel system 20 is free from a roofing structure between the racking assembly and the frame assembly. Unless specifically excluded, clamping assembly 108 may include one or more components of other clamping assemblies described in this specification. Clamping assembly 108 may include a first clamping member 110, a second clamping member 112, and a fastener 114, as shown in FIG. 7.

The first clamping member may include a base portion 116 and a channel receiver (or receiving portion) 118. The base portion may include a first surface 120 and a second surface 122. The first surface may be configured to support a portion of a first solar panel, while the second surface may be configured to support a portion of a second solar panel. The first and second surfaces may be coplanar or within first plane F. Alternatively, the first and second surface may be in separate planes (not shown). Additionally, or alternatively, the first clamping member may be free from one or more voids between the first and second surfaces.

Base portion 116 also may include a third surface 124 within second plane S parallel to first plane F. Additionally, the base portion may include a first wall 126 and a second wall 128, which may connect the first and second surfaces and the third surface to form a closed hollow structure 130, as shown in FIG. 7. Moreover, base portion 116 may include a fourth surface 132 connected to but external closed hollow structure 130. The fourth surface may be coplanar with third surface 124 or may be on a different plane from that surface. Fourth surface 132 may include one or more grooves 133 configured to receive one or more fasteners 114. Furthermore, the base portion may include one or more openings 134 configured to receive an end cap (not shown). Fastener(s) 114 may be configured to secure fourth surface 132 (and/or third surface 124) to the frame assembly.

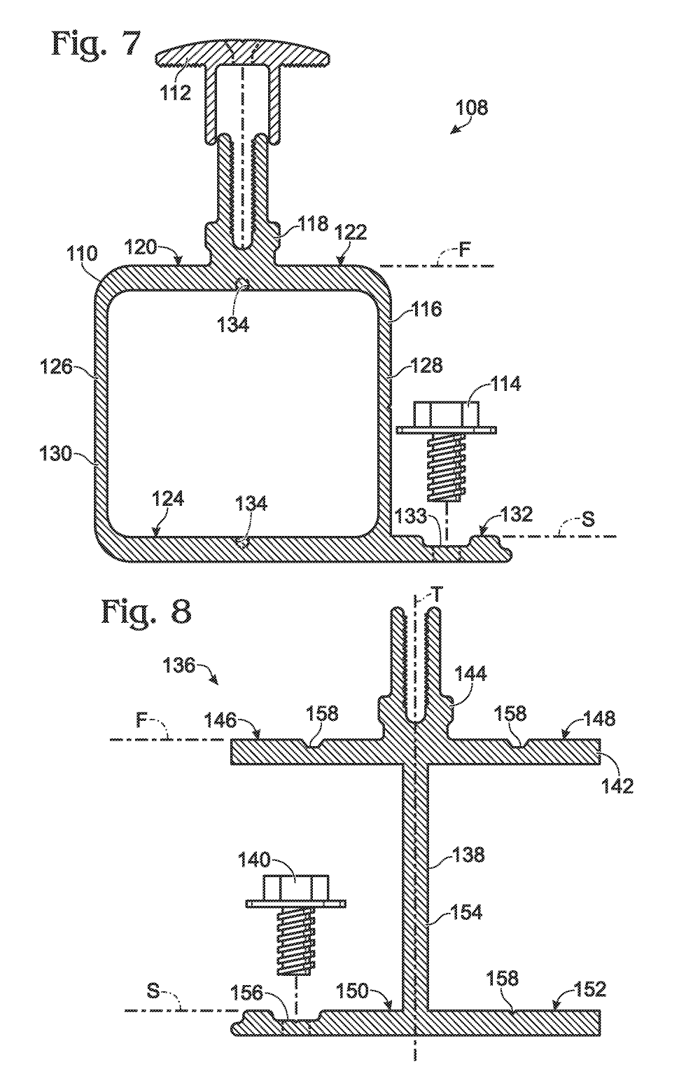

FIG. 8 shows another example of a clamping assembly 50, which is generally indicated at 136, that may be used to directly attach solar panels 26 to frame assembly 22 such that solar panel system 20 is free from a roofing structure between the racking assembly and the frame assembly. Unless specifically excluded, clamping assembly 136 may include one or more components of other clamping assemblies described in this specification. Clamping assembly 136 may include a first clamping member 138, a second clamping member similar to one or more of the second clamping members described in this specification, and a fastener 140, as shown in FIG. 8.

The first clamping member may include a base portion 142 and a channel receiver (or receiving portion) 144. The base portion may include a first surface 146 and a second surface 148. The first surface may be configured to support a portion of a first solar panel, while the second surface may be configured to support a portion of a second solar panel. The first and second surfaces may be coplanar or within first plane F. Alternatively, the first and second surface may be in separate planes (not shown). Additionally, or alternatively, the first clamping member may be free from one or more voids between the first and second surfaces.

Base portion 142 also may include a third surface 150 and a fourth surface 152 within second plane S parallel to first plane F. Additionally, the base portion may include a first wall 154 disposed between the third and fourth surfaces, which may connect the first and second surfaces and the third and fourth surfaces, as shown in FIG. 8. The first wall may define a third plane T that may be generally perpendicular to the first and second planes. In some embodiments, the channel receiver may generally be within the third plane. The third and/or fourth surfaces may include a groove 156 configured to receive fastener(s) 140. Additionally, the first, second, third, and/or fourth surfaces may include one or more channels 158, which may be configured to drain and/or direct water falling on the clamping assemblies. Fastener(s) 140 may be configured to secure the third and/or fourth surfaces to the frame assembly.

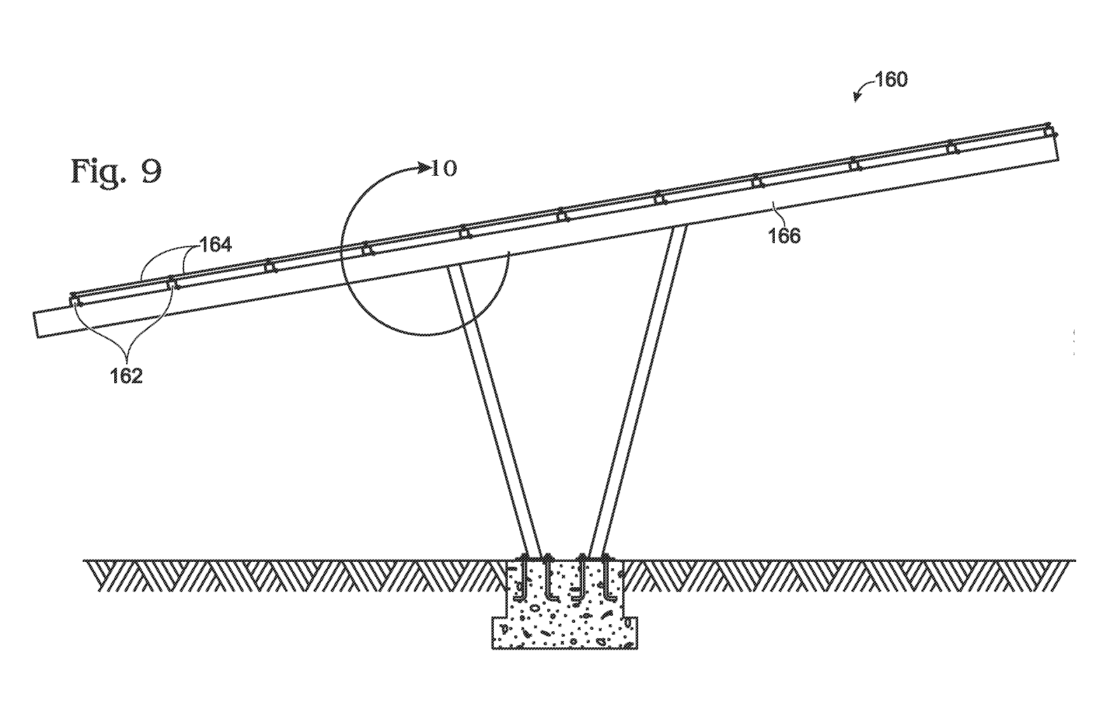

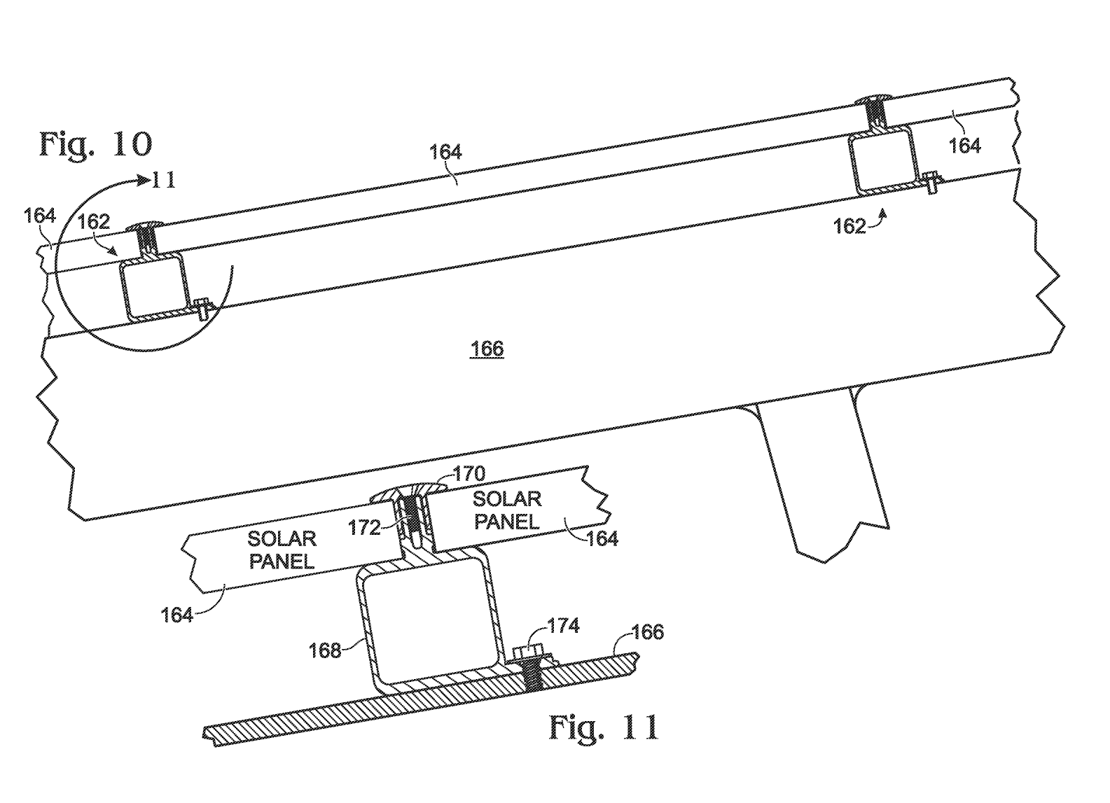

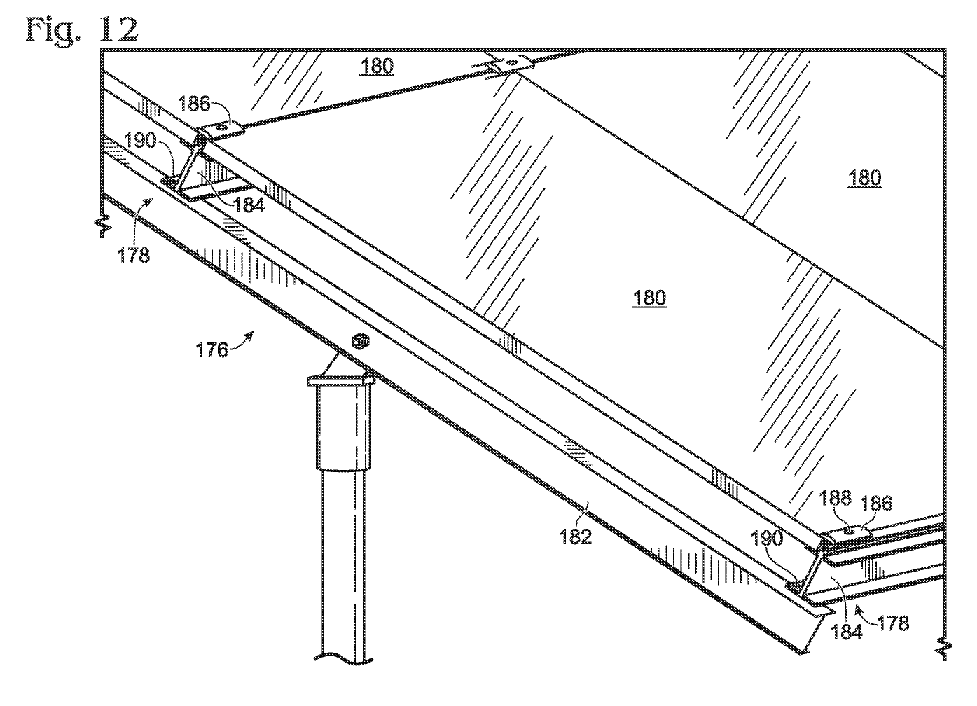

FIG. 9 shows another example of a solar panel system, which is generally indicated at 160. Unless specifically excluded, solar panel system 160 may include one or more components of the solar panel systems described in this specification. Solar panel system 160 may include a plurality of clamping assemblies 162 securing solar panels 164 to frame assembly 166. Unlike the solar panel system of FIG. 1, solar panel system 160 is free from (or does not include) a roof structure between the clamping assemblies and the frame assembly. Each clamping assembly 162 may include a first clamping member 168, a second clamping member 170, a first fastener 172, and a second fastener 174, as shown in FIGS. 10-11.

FIG. 12 shows another example of a solar panel system, which is generally indicated at 176. Unless specifically excluded, solar panel system 176 may include one or more components of the solar panel systems described in this specification. Solar panel system 176 may include a plurality of clamping assemblies 178 securing solar panels 180 to frame assembly 182. Similar to the solar panel system of FIGS. 9-11, solar panel system 176 is free from (or does not include) a roof structure between the clamping assemblies and the frame assembly. Each clamping assembly 178 may include a first clamping member 184, a second clamping member 186, a first fastener 188, and a second fastener 190, as shown in FIG. 12.

Solar panel systems, such as the solar panel systems of FIGS. 9-12 may be described as having one or more solar panels (i.e., PV Modules) directly attached to the substantially planar support region of the frame assembly with a racking assembly, such that the solar panels form the roof that defines the covered space. Additionally, the structural support portions, such as the portions below the first and second surfaces, of the first clamping members of FIGS. 9-12 may be referred to as a “purlin” or “joist portion.”

Roofs comprised of solar panels attached directly to the frame assembly by a racking assembly, where the solar panels themselves form the roof that defines the covered space, has advantages over roofs comprised of a roof structure with solar panels attached to the roof structure. When solar panels are attached to a roof structure, the air space between the solar panels and the roof often heats considerably during normal exposure of the solar panel to sunlight, due in part to inadequate ventilation. This pocket of warm or hot air, in turn, may heat the solar panels to a degree that affects their performance. Roofs that do not include a roof structure, but instead have solar panels attached directly to the frame by a racking system do not suffer from this problem, because the air surrounding the solar panels is adequately ventilated.

### III. Examples of Uses for Solar Panel Systems

SS #1: An 8×8′ unit may provide over 1.05 kw of power. Secondary uses may include backyard storage shed to protect tools, garden supplies, off-season sporting equipment and lawn equipment from inclement weather. It may also function as a shaded play area, dining spot, or potting shed . . . the possibilities are endless.

SS #2: A 10×12 unit may double the capacity for power, with 2.10 kw. Secondary uses may include a car port to protect your vehicles from snow, ice, rain and sun, and a backyard storage shed to protect tools, garden supplies, off-season sporting equipment and lawn equipment from inclement weather. It may also function as a shaded play area, dining spot, or potting shed . . . the possibilities are endless.

SS #4: A 12×12 unit may provide approximately 4.2 kw of solar power. Secondary uses may include a car port to protect your vehicles from snow, ice, rain and sun, and a backyard storage shed to protect tools, garden supplies, off-season sporting equipment and lawn equipment to guard against inclement weather. It may also function as a shaded play area, dining spot, or potting shed . . . the possibilities are endless.

SS #8: A 22×28 unit may provide approximately 7.88 kw of power and may be perfect for larger properties or small commercial/industrial sites. Secondary uses may include a double carport, and a large storage shed to protect tools and other equipment from inclement weather.

SS Custom/Industrial Units: For custom structures with specific power, size and/or shape requirements, or for larger industrial or commercial structures with greater power requirements, structures may be custom designed to meet specific needs, ranging in size from approximately 1 kw to 100 kw. Secondary uses may include any of the uses describe above, as well as protecting RV's, golf carts, boats, tractors, even airplanes from inclement weather.

The disclosure set forth above encompasses multiple distinct inventions with independent utility. While each of these inventions has been disclosed in a preferred form or method, the specific alternatives, embodiments, and/or methods thereof as disclosed herein are not to be considered in a limiting sense, as numerous variations are possible. The present disclosure includes all novel and non-obvious combinations and subcombinations of the various elements, features, functions, properties, methods and/or steps disclosed herein. Similarly, where any disclosure above recites “a” or “a first” element, step of a method, or the equivalent thereof, such disclosure should be understood to include one or more such elements or steps, neither requiring nor excluding two or more such elements or steps.

Inventions embodied in various combinations and subcombinations of features, functions, elements, properties, steps and/or methods may be claimed through presentation of claims in a related application. Such claims, whether they are directed to a different invention or directed to the same invention, whether different, broader, narrower, or equal in scope to the original claims, are also regarded as included within the subject matter of the present disclosure.

What is claimed is:

1. A clamping assembly for securing two or more solar panels to a frame assembly, comprising:
an extruded first clamping member having first and second surfaces and a receiving portion disposed between the first and second surfaces, the first surface configured to support a portion of a first solar panel, and the second surface configured to support a portion of a second solar panel, the first and second surfaces being within a first plane and the first clamping member being free from a void between the first and second surfaces;
a second clamping member configured to be attached to the receiving portion, the first and second solar panels being disposed between the first and second clamping members; and
a first fastener configured to be at least partially received by the receiving portion of the first clamping member and the second clamping member to secure together the first and second clamping members and the first and second solar panels.

2. The clamping assembly of claim 1, wherein at least one of the first and second surfaces includes a groove, further comprising a second fastener configured to be at least partially received in the groove and to secure the first clamping member to the frame assembly.

3. The clamping assembly of claim 1, wherein the first clamping member includes a third surface within a second plane parallel to the first plane, and first and second walls connecting the first and second surfaces and the third surface to form a closed hollow structure, further comprising a second fastener configured to secure the third surface to the frame assembly.

4. The clamping assembly of claim 1, wherein the first clamping member includes third and fourth surfaces within a second plane that is parallel to the first plane, and a first wall connecting the first and second surfaces and the third and fourth surfaces further comprising a second fastener configured to be at least partially received in one of the third and fourth surfaces and to secure the one of the third and fourth surfaces to the frame assembly.

5. A solar panel racking system, comprising:
a plurality of clamping assemblies, including:
an extruded first clamping member having a receiving portion disposed between first and second surfaces, the first surface configured to support a portion of a first solar panel, and the second surface configured to support a portion of a second solar panel, the first and second surfaces being within a first plane and the first clamping member being free from a void between the first and second surfaces;
a second clamping member configured to be attached to the receiving portion, the first and second solar panels being disposed between the first and second clamping members; and
a first fastener configured to be at least partially received by the receiving portion of the first clamping member and the second clamping member to secure together the first and second clamping members and the first and second solar panels; and
a frame assembly configured to support the plurality of clamping assemblies on a surface.

6. The system of claim 5, wherein the first clamping member includes a third surface within a second plane that is parallel to the first plane.

7. The system of claim 6, wherein the first clamping member includes first and second walls connecting the first and second surfaces and the third surface to form a closed hollow structure.

8. The system of claim 7, wherein the solar panel racking system is free from a roofing structure between the plurality of clamping assemblies and the frame assembly, further comprising a second fastener configured to secure the third surface to the frame assembly.

9. The system of claim 7, wherein the solar panel racking system is free from a roofing structure between the plurality of clamping assemblies and the frame assembly, wherein the first clamping member includes a fourth surface coplanar with the third surface but external the closed hollow structure, further comprising a second fastener configured to secure the fourth surface to the frame assembly.

10. The system of claim 7, wherein the first and second walls are generally perpendicular to the first, second, and third surfaces.

11. The system of claim 5, wherein the first clamping member includes third and fourth surfaces within a second plane parallel to the first plane.

12. The system of claim 11, wherein the solar panel racking system is free from a roofing structure between the plurality of clamping assemblies and the frame assembly, further comprising a second fastener configured to secure at least one of the third and fourth surfaces to the frame assembly.

13. The system of claim 11, wherein the first clamping member includes a first wall disposed between the third and fourth surfaces and connecting the first and second surfaces and the third and fourth surfaces.

14. The system of claim 13, wherein the first wall defines a third plane that is generally perpendicular to the first and second planes.

15. The system of claim 14, wherein the receiving portion is generally within the third plane.

16. The system of claim 5, wherein at least one of the first and second surfaces includes a groove configured to receive a fastener, further comprising a roof structure disposed between the plurality of clamping assemblies and the frame assembly, and a second fastener configured to be at least partially received in the groove to attach the at least one of the first and second surfaces to the roof structure.

17. The system of claim 16, wherein the roof structure includes a plurality of mounts, and the second fastener is configured to be at least partially received in a mount of the plurality of mounts.

18. A solar panel system, comprising:
a plurality of solar panels, including first and second solar panels;
a plurality of clamping assemblies, including:
an extruded first clamping member having a receiving portion disposed between first and second surfaces, the first surface configured to support a portion of the first solar panel, and the second surface configured to support a portion of the second solar panel, the first and second surfaces being within a first plane and the first clamping member being free from a void between the first and second surfaces;
a second clamping member configured to be attached to the receiving portion, the first and second solar panels being disposed between the first and second clamping members; and
a first fastener configured to be at least partially received by the receiving portion of the first clamping member and the second clamping member and to secure together the first and second clamping members and the first and second solar panels; and
a frame assembly configured to support the plurality of solar panels on a surface, wherein the plurality of clamping assemblies secure the plurality of solar panels to the frame assembly.

19. The system of claim 18, wherein the solar panel system is free from a roofing structure between the plurality of clamping assemblies and the frame assembly, wherein the plurality of clamping assemblies further includes a second fastener configured to secure the first clamping member to the frame assembly.

20. The system of claim 18, wherein at least one of the first and second surfaces includes a groove configured to receive a fastener, further comprising a roof structure disposed between the plurality of clamping assemblies and the frame assembly, and a second fastener configured to be at least partially received in the groove to attach the at least one of the first and second surfaces to the roof structure.
